(19) United States
(12) Patent Application Publication
(10) Pub. No.: US 2004/0221888 A1
(43) Pub. Date: Nov. 11, 2004

(54) Dye-sensitized solar cell and manufacturing method thereof

(75) Inventors: Atsushi Fukui, Kashiba-shi (JP); Liyuan Han, Kitakatsuragi-gun (JP)

Correspondence Address: NIXON & VANDERHYE, PC, 1100 N GLEBE ROAD, 8TH FLOOR, ARLINGTON, VA, 22201-4714, US

(73) Assignee: Sharp Kabushiki Kaisha, Osaka (JP)

(21) Appl. No.: 10/815,976

(22) Filed: Apr. 2, 2004

(30) Foreign Application Priority Data
Apr. 4, 2003 (JP) 2003-101571
Feb. 27, 2004 (JP) 2004-054568

(51) Int. Cl. H01L 31/00

(52) U.S. Cl. 136/263; 136/252; 429/111; 438/85; 438/82

(57) ABSTRACT

A dye-sensitized solar cell comprising a transparent conductive layer, a porous semiconductor layer on which a dye sensitizer is adsorbed, a carrier transport layer and an counter electrode which are formed in this order on a transparent substrate,

wherein an absorbance peak of the porous semiconductor layer is located on a shorter wavelength side of the absorbance spectrum than that of the porous semiconductor layer observed immediately after the dye sensitizer is adsorbed.

### CROSS-REFERENCE TO RELATED APPLICATIONS

This application is related to Japanese Patent Applications No. 2003-101571 filed on Apr. 4, 2003 and No. 2004-54568 filed on Feb. 27, 2004 whose priority is claimed under 35 USC § 119, the disclosure of which is incorporated by reference in its entirety.

### BACKGROUND OF THE INVENTION

1. Field of the Invention

The invention relates to a dye-sensitized solar cell and a manufacturing method thereof. More particularly, the invention relates to a dye-sensitized solar cell with a high photoelectric conversion efficiency and a manufacturing method thereof.

2. Description of the Related Art

Solar cells utilizing sunbeam have drawn attention as an alternative energy source to fossil fuels and various researches have carried out. At present, solar cells made of polycrystalline silicon or amorphous silicon have been practically used as the mainstream. However, they are problematic in high costs and large energy consumption in manufacturing them and in the use of highly toxic materials such as gallium and arsenic.

Under such circumstances, a dye-sensitized solar cell obtained at a relatively low cost has attracted attention widely. The dye-sensitized solar cell is based on configured by, for example, a transparent conductive layer formed on a transparent substrate, an counter electrode, a porous semiconductor layer supporting (or adsorbing) a dye sensitizer, and a carrier transport layer which are interposed between the transparent conductive layer and the counter electrode.

For example, J. Am. Ceram. Soc., 80(12) 3157-3171(1997) describes a manufacturing method of a dye-sensitized solar cell based on a porous titanium oxide thin film electrode on which a dye sensitizer such as a transition metal complex is adsorbed. In the method, a dye-sensitized solar cell is manufactured as follows: a transparent conductive layer and a titanium oxide film as a porous semiconductor layer are successively formed on a transparent substrate; the resultant substrate is immersed in a solvent containing the dye sensitizer; an electrolytic solution containing a redox system is titrated to the substrate in a dropwise manner; and an counter electrode is overlaid on a porous electrode.

When visible light is radiated to the porous electrode of the dye-sensitized solar cell, the light adsorption by the dye sensitizer on the semiconductor layer, and electron excitations in the dye molecule occur, and the excited electrons are injected in the semiconductor electrode. Accordingly, electrons are generated on the electrode (transparent conductive layer) side and move to the counter electrode through an external electric circuit. The electrons in the counter electrode are moved through hole or ion transporting layer and returned to the dye. The electric energy is generated by repeating this process. Such steps are repeated to generate electric energy and achieve a high photoelectric conversion efficiency. However, in comparison with Si solar cell, the conversion efficiency of dye sensitizing solar cell should be improved. This means the short-circuit current and the open-circuit voltage should be improved.

In order to increase the open-circuit voltage, leak current from the semiconductor electrode to the dye sensitizer or to the carrier transport layer has to be decreased.

A various methods for decrease the leak current in a dye-sensitized solar cell have been proposed (see Japanese Unexamined Patent Publications No. 2002-75471, No. 2002-280087, No. 2002-352869 and No. 2001-167807).

Especially, it is well known that addition of tert-butylpyridine to an electrolytic solution is effective. However, tert-butylpyridine, which is volatile, is not suitable for practical application, and the obtained open-circuit voltage is rather low as compared with a theoretically expected open-circuit voltage.

### SUMMARY OF THE INVENTION

It is therefore an object of the invention to provide a dye-sensitized solar cell with a high open-circuit voltage and a high photoelectric conversion efficiency as well by decreasing the leak current.

The invention provides a dye-sensitized solar cell comprising a transparent conductive layer, a porous semiconductor layer on which a dye sensitizer is adsorbed, a carrier transport layer and an counter electrode which are formed in this order on a transparent substrate,

wherein an absorbance peak of the porous semiconductor layer is located on a shorter wavelength side of the absorbance spectrum than that of the porous semiconductor layer observed immediately after the dye sensitizer is adsorbed.

The invention also provides a manufacturing method of a dye-sensitized solar cell comprising a transparent conductive layer, a porous semiconductor layer on which a dye sensitizer is adsorbed, a carrier transport layer and an counter electrode which are formed in this order on a transparent substrate, comprising: the step of shifting an absorbance peak of the porous semiconductor layer to a shorter wavelength side of the absorbance spectrum than that of the porous semiconductor layer observed immediately after the dye sensitizer is adsorbed.

According to the invention, it is possible to provide a dye-sensitized solar cell having a high open-circuit voltage and a high photoelectric conversion efficiency as well by decreasing the leak current.

### BRIEF DESCRIPTION OF THE DRAWINGS

FIG. 1 is a schematic cross-sectional view showing a layer structure of a dye-sensitized solar cell of the invention.

### DESCRIPTION OF THE PREFERRED EMBODIMENT

In the invention, term “absorbance peak” means the peak observed at the longest wavelength side by an absorbance measurement with an absorbance measurement apparatus. In the case where the light scattering effect by the semiconductor is slight, the absorbance peak disappears and a wavelength region of the absorbance spectrum in which the absorbance is not changed regardless of the wavelength alteration appears. The absorbance peak in that case means the wavelength value at which the increase of the absorbance corresponding to the wavelength alteration becomes zero.

Also in the invention, term “absorbance peak of the porous semiconductor layer observed immediately after the dye sensitizer is adsorbed” means the absorbance peak measured immediately after the dye sensitizer is adsorbed in the porous semiconductor layer and then washing with a solvent such as an alcohol is carried out. In general, it means an absorbance peak definitely determined if a dye and a semiconductor (titanium oxide or the like) for adsorbing the dye are determined.

With respect to a dye-sensitized solar cell comprising a transparent conductive layer, a porous semiconductor layer on which a dye sensitizer is adsorbed, a carrier transport layer and an counter electrode which are formed in this order on a transparent substrate, a manufacturing method thereof comprises the step of shifting an absorbance peak of the porous semiconductor layer to a shorter wavelength side of the absorbance spectrum than that of the porous semiconductor layer observed immediately after the dye sensitizer is adsorbed. Accordingly, the leaks current can be decreased; therefore, it is possible to obtain a dye-sensitized solar cell having a high open-circuit voltage and a high photoelectric conversion efficiency as well. In the following description, term “porous semiconductor layer having a dye sensitizer adsorbed therein” may be referred to as “semiconductor electrode” or “photoelectrode”.

In other words, electrons injected from a dye sensitizer occupying the lowest level of the conduction of a semiconductor electrode and it is considered that the leak current of electrons is generated when the back electrons transfer from conduction band to the LUMO level or the HOMO level of the dye sensitizer occurs to result in decrease of the open-circuit voltage.

The shift of the absorbance peak to the shorter wavelength side of the absorbance spectrum means that the energy gap between the LUMO (Lowest Unoccupied Molecular Orbit) level and the HOMO (Highest Occupied Molecular Orbit) level is increased, the LUMO level is heightened, and that the HOMO level is lowered.

It is considered that if the HOMO level is lowered, the energy gap between the lowest level of the conduction and the HOMO level is increased and the leak current of electrons (reverse electric current) to the HOMO level of the dye sensitizer from the semiconductor electrode can be decreased. The same phenomena relevant to the LUMO level may be considered to be possible. Accordingly, if the absorbance peak is shifted to the shorter wavelength side of the absorbance spectrum, the open-circuit voltage is supposedly improved.

An embodiment of the invention will be described with reference to the drawing. However, the invention is not limited to the following embodiment, and modifications and substitutions to specific conditions and structures can be made without departing from the spirit and scope of the invention.

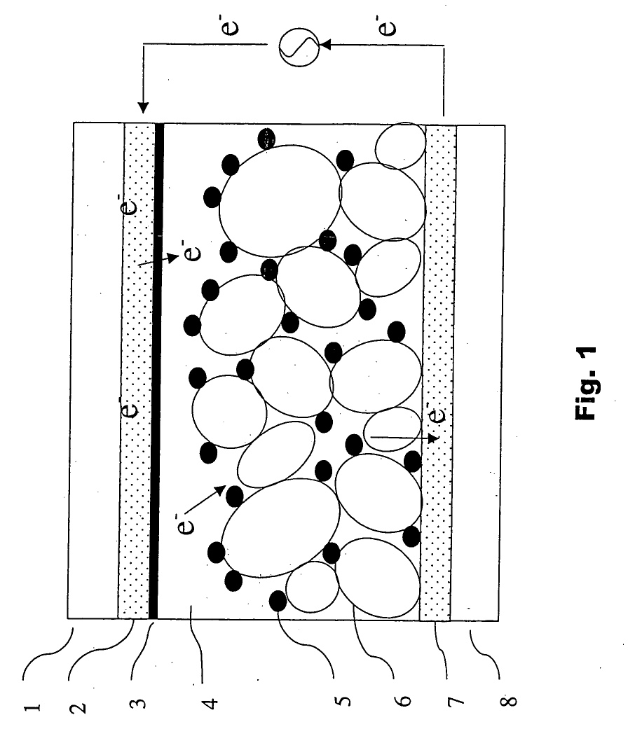

FIG. 1 is a schematic cross-sectional view showing the layer structure of a dye-sensitized solar cell of the invention. In FIG. 1, 1 and 8 denote supporting substrates; 2 and 7 denote transparent conductive layers; 3 denotes a platinum layer; 4 denotes a carrier transport layer; 5 denotes a dye sensitizer; 6 denotes a porous semiconductor layer; e⁻ and arrow marks show the flow of an electric current. The transparent conductive layer 2 and the platinum layer 3 in combination are all together called as an counter electrode in some cases.

At least one of the supporting substrates 1 and 8 is transparent, and examples thereof include a glass substrate, a plastic substrate and the like. The thickness is not particularly limited as long as it is possible to provide a suitable strength to a thin film type solar cell.

The transparent conductive layers 2 and 7 are made of a transparent conductive material such as ITO, SnO₂, CuI, and ZnO and may be formed on the respective supporting substrates 1 and 8 by well-known methods, for example, a vapor-phase method such as a vacuum deposition method, a sputtering method, a CVD method and a PVD method and a coating method such as a sol-gel method. The film thickness of these films is preferably about 0.1 to 5 μm.

Together with the transparent conductive layer 7 formed on the supporting substrate 8, the counter electrode including the transparent conductive layer 2 and the platinum layer 3 forms a pair of electrodes. FIG. 1 shows an counter electrode having two layers of the transparent conductive layer 2 and the platinum layer 3. The counter electrode may be formed of an other transparent or opaque conductive film. Examples of such a conductive film may include films with a structure of a single layer or a plurality of layers of n-type or p-type element semiconductor (e.g., silicon and germanium); compound semiconductor (e.g., GaAs, InP, ZnSe and CsS); metals such as gold, silver, copper and aluminum; refractory metals such as titanium, tantalum and tungsten; and transparent conductive materials such as ITO, SnO₂, CuI and ZnO.

Such conductive films may be formed by well known methods, for example, a vapor-phase method such as a vacuum deposition method, a sputtering method, a CVD method and a PVD method and a coating method such as a sol-gel method. The film thickness of these films is preferably about 1 to 5 μm.

The platinum layer 3 also functions as a protective layer, and is formed by methods such as the sputtering method, thermal decomposition of chloroplatinic acid and electrodeposition. The thickness of the platinum layer 3 is preferably about 1 to 1000 nm.

The porous semiconductor layer 6 is made of semiconductor nanoparticles and formed on the transparent conductive layer 2. The porous semiconductor layer 6 is preferably in the form of a porous film; however, it may be in the form of a granular or a film.

The semiconductor nanoparticles are not particularly limited as long as they are commonly used for photoelectric conversion materials, and examples thereof include nanoparticles of oxides such as titanium oxide, zinc oxide, tin oxide, niobium oxide, zirconium oxide, cerium oxide, tungsten oxide, silicon oxide, aluminum oxide, nickel oxide, barium titanate, strontium titanate, cadmium sulfide, CuAlO₂ and SrCu₂O₂. These oxides may be used alone or in combination.

Commercialized ones may be used as the semiconductor nanoparticles and the average particle of the particles is, for example, 1 to 2000 nm.

Among the above-mentioned oxides, in terms of the stability and the safety, titanium oxide is particularly preferable. Titanium oxide may include various kinds of form in a narrow definition such as anatase type titanium oxide, rutile type titanium oxide, amorphous titanium oxide, metatitanic acid and orthotitanic acid, and titanium hydroxide and hydrated titanium oxide as well.

A method for forming the porous semiconductor layer on the transparent conductive layer is not particularly limited and the following known methods and their combination may be exemplified:

(1) a method involving applying a suspension containing semiconductor nanoparticles to a transparent conductive layer, and drying and/or calcining the suspension;

(2) a method such as a CVD method and a MOCVD method using a single gas or a gas mixture of two or more kinds of gases containing the elements forming the semiconductor;

(3) a method such as a PVD method, a deposition method and a sputtering method using a single solid substance, combinations of a plurality of solid substances, or a solid of a compound containing the elements forming the semiconductor as a raw material; and

(4) a method such as a sol-gel method or based on electrochemical redox reaction.

In the method (1), first, semiconductor nanoparticles and, optionally, a dispersant are added to a Glyme type solvent such as ethylene glycol monomethyl ether; an alcohol type solvent such as isopropyl alcohol; an alcohol type mixed solvent of isopropyl alcohol/toluene; or water to produce a suspension, and the suspension is applied on a transparent conductive layer. As an application method, known methods such as a doctor blade method, a squeeze method, a spin coating method and a screen printing method may be used. After that, the coating solution is dried and calcined to obtain the porous semiconductor layer. The conditions such as the temperature, duration, ambient gas and the like at the time of drying and calcining may properly be adjusted depending on the types of the transparent conductive layer and semiconductor particles to be employed. For example, the drying and calcining are carried out at a temperature of about 50 to 800° C. for about 10 seconds to 12 hours in atmospheric air or an inert gas atmosphere. The drying and calcining may be carried out once at a constant temperature or two or more times while the temperature being changed.

The thickness of the porous semiconductor layer is not particularly limited and, in terms of light transmittance and photoelectric conversion efficiency, it is preferable to be about 0.1 to 50 μm. In order to improve the photoelectric conversion efficiency, it is required to adsorb a larger quantity of a dye in the porous semiconductor layer and for that, the porous semiconductor layer is preferable to have a specific surface area as high as about 10 to 200 m²/g.

As the dye sensitizer 5 to be adsorbed in the porous semiconductor layer and having the function, as a photosensitizer, of injecting electrons generated by the light absorbance to the porous semiconductor layer, metal complex dyes and organic dyes which have absorbance in a wide range of a visible light region and/or an IR region can be used. In order to firmly adsorb the dye in the porous semiconductor layer, those having interlocking groups such as a carboxylic acid group, a carboxylic anhydride group, an alkoxy group, a hydroxyl group, a hydroxyalkyl group, a sulfonic acid group, an ester group, a mercapto group and a phosphonyl group in the dye molecule are preferable. In particular, a carboxylic acid group and a carboxylic anhydride group are especially preferable. It is noted that the interlocking groups provide electric bonds for making the electron transportation between the dye in the excited state and the conduction of the porous semiconductor layer. In general, the dye is fixed to the porous semiconductor layer through the interlocking groups.

Examples of the organic dyes may include azo type dyes, quinone type dyes, quinone-imine type dyes, quinacridone type dyes, squarylium type dyes, cyanine type dyes, merocyanine type dyes, triphenylmethane type dyes, xanthene type dyes, porphyrin type dyes, perylene type dyes, indigo type dyes and phthalocyanine type dyes.

Examples of the metal complex dyes may include metal complexes of Cu, Ni, Fe, Co, V, Sn, Si, Ti, Ge, Cr, Zn, Ru, Mg, Al, Pb, Mn, In, Mo, Y, Zr, Nb, Sb, La, W, Pt, Ta, Ir, Pd, Os, Ga, Tb, Eu, Rb, Bi, Se, As, Sc, Ag, Cd, Hf, Re, Au, Ac, Tc, Te, Rh and the like. In particular, phthalocyanine type or ruthenium type metal complex dyes are preferable and ruthenium type metal complex dye is especially preferable.

Specific examples thereof may include cis-bis(isothiocyanato)bis(2,2′-bipyridyl-4,4′-dicarboxylato)ruthenium(II), cis-bis(isothiocyanato)bis(2,2′-bipyridyl-4,4′-dicarboxylato)-ruthenium(II)bis-tetrabutylammonium and tris(isothiocyanato)-ruthenium(II)-2,2′:6′,2′-terpyridine-4,4′,4″-tricarboxylic acid, tris-tetrabutylammonium salt having the formula (1):

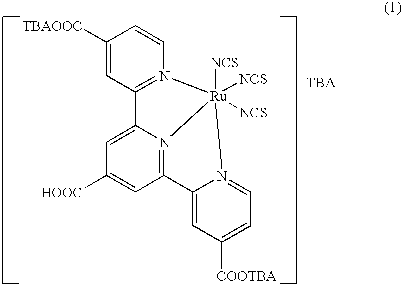

(wherein TBA is tetrabutylammonium residual group).

These metal complex dyes are commercially available in trade names, Ruthenium 535 dye, Ruthenium 535-bisTBA dye and Ruthenium 620-1H3TBA dye (all made by Solaronix, Swiss).

As a method for adsorbing the dye sensitizer in the porous semiconductor layer, a method involving immersing the porous semiconductor layer in a solution containing the dye sensitizer (a dye adsorption solution) can be used. Specific examples of the solvent to dissolve the dye sensitizer therein may include organic solvents such as alcohol, toluene, acetonitrile, THF, chloroform, dimethylformamide and the like. In general, these solvents are preferable to be purified and two or more of them can be used in the form of a mixture. The concentration of the dye in the solvent can properly be adjusted depending on the types of the dye and solvent to be used and also on the conditions of the adsorption step and it is preferably 1×10⁻5 mol/l or more.

The conditions of the temperature, pressure and duration in the step of immersing the porous semiconductor layer in the dye adsorption solution can properly be adjusted. The immersion may be carried out only once or a plurality of times and, after the immersion, drying may be carried out properly.

Before the dye sensitizer is adsorbed in the porous semiconductor layer, treatment for activating the semiconductor surface, for example, treatment by TiCl₄ may be carried out based on the necessity.

Next, by the step of shifting the absorbance peak of the porous semiconductor layer to a shorter wavelength side of the absorbance spectrum, the absorbance peak of the porous semiconductor layer is shifted to the shorter wavelength side of the absorbance spectrum by 10 to 60 nm than that of the porous semiconductor layer observed immediately after the dye sensitizer is adsorbed. The step of shifting the absorbance peak to the shorter wavelength side of the absorbance spectrum is carried out after the dye sensitizer is adsorbed in the porous semiconductor layer, that is in the step of forming the porous semiconductor layer on the transparent conductive layer and adsorbing the dye sensitizer therein. The method is not particularly limited, and thermal treatment, chemical treatment, and light radiation can be exemplified.

The thermal treatment can be carried out under atmospheric air or an inert gas atmosphere such as nitrogen gas in a drying furnace after the porous semiconductor layer is washed with a solvent such as ethanol. The heating temperature is preferably about 100 to 180° C. and the heating duration is preferably about 1 minute to 1 hour.

The chemical treatment may be carried out by using a solution containing at least one heteroatom-containing cyclic compound preferably after the porous semiconductor layer adsorbed is washed with a solvent such as ethanol.

This treatment is preferably a treatment of immersing a substrate comprising the porous semiconductor layer in the solution. The immersion duration can properly be adjusted depending on the concentration of the solution and it is generally about 1 minute to 30 hours. The treatment temperature is not particularly limited and properly adjusted based on the necessity.

If the heteroatom-containing cyclic compound is a solid, it is used while being dissolved in a solvent, for example, an alcohol type solvent such as ethanol and methanol; a nitrile type solvent such as acetonitrile and propionitrile; and a non-protonic solvent such as N,N′-dimethylformamide and dimethyl sulfoxide. Also, even if the heteroatom-containing cyclic compound is a liquid, it may be dissolved in the above-mentioned solvent. The solvent may be mixed with another compound.

The concentration of the solution may be adjusted properly depending on the types of the dye sensitizer and the heteroatom-containing cyclic compound and it may be, for example, about 0.5 M.

The mechanism of the shift of the absorbance peak to the shorter wavelength side of the absorbance spectrum by the chemical treatment is not clear; however, it is better to use a larger amount of the solution and the amount is preferably at least 30 times, more preferably at least 100 times, as much as that of the porous semiconductor layer by volume. If the amount of the solution is less than 30 times as much as that of the porous semiconductor layer by volume, the absorbance peak is not so much changed and the effect on the improvement of Voc is insignificant and thus it is not preferable.

Examples of the heteroatom-containing cyclic compound may include monocyclic compounds such as furan, tetrahydrofuran, dioxole, dioxolan, thiophene, tetrahydrothiophene, pyrrole, imidazole, pyran, tetrahydropyran, dioxene, dioxane, dioxine, trioxane and their derivatives; dicyclic compounds such as quinolizine, quinoxaline, quinoline, 2-methylbenzothiazole, 2-methylbenzoxozole, and their derivatives; and tricyclic compounds such as carbazole, carboline, phenazine and their derivatives.

In particular, nitrogen-containing cyclic compounds such as quinolizine, quinoxaline, quinoline and their derivatives are preferable and compounds having two or more nitrogen atoms are especially preferable.

Further, nitrogen-containing cyclic compounds including a substituted or unsubstituted 5-membered ring such as 2-methylbenzothiazole, 2-methylbenzoxazole, carbazole and their derivatives are also preferable.

As the derivatives of the heteroatom-containing compounds, for example, imidazole can be used. Further, examples of other derivatives of the heteroatom-containing compounds may include alkylated imidazole salts such as ethylimidazolium iodide, ethylmethylimidazolium iodide, methylpropylimidazolium iodide, dimethylpropylimidazolium iodide and hexylmethylimidazolium iodide.

Light radiation may be carried out by using light of a solar simulator in atmospheric air or in atmosphere of an inert gas such as nitrogen, preferably after the porous semiconductor layer washes with a solvent such as ethanol. The intensity of the light may be, for example, about 0.1 to 10 kW/m² and the radiation duration is about 1 minute to 6 hours. The intensity is equivalent to about 1/10 to 10 times as high as that of natural light. The porous semiconductor layer is sometimes heated at the time of light radiation, however it is no need to adjust the temperature.

As a dye sensitizer, Ruthenium 535 dye, Ruthenium 535-bisTBA, Ruthenium 620-1H3TBA dye or a dye I defined by the following formula was adsorbed in a porous semiconductor layer of titanium oxide and subjected to thermal treatment (heat temperature: 100° C., heating duration: 1 hour) or chemical treatment (by immersion in an acetonitrile solution of 0.5 M dimethylpropylimidazolium iodide at 25° C. for 1 hour), and the absorbance peak measurement was carried out before and after the treatment to obtain the results shown in Table 1.

TABLE 1

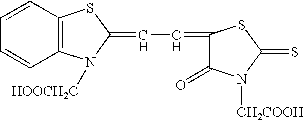

(nm)

| | | Ruthenium | Ruthenium | |
|---|---|---|---|---|
| | Ruthenium | 535- | 620- | |
| Dye sensitizer | 535 | bisTBA | 1H3TBA | Dye I |
| Absorbance peak | 540 | 530 | 620 | 460 |
| immediately after | | | | |
| adsorption | | | | |
| Absorbance peak | 509 | 521 | 609 | 451 |
| after thermal | | | | |
| treatment | | | | |
| Absorbance peak | 480 | 492 | 558 | 444 |
| after chemical | | | | |
| treatment | | | | |

From the results shown in Table 1, it can be understood that the absorbance by peak of the porous semiconductor layer subjected to the thermal treatment or the chemical treatment was shifted to the shorter wavelength side of the absorbance spectrum than the absorbance peak immediately after the adsorption. The absorbance peak of the porous semiconductor layer adsorbed Ruthenium 535 dye, Ruthenium 535-bisTBA dye and Ruthenium 620-1H3TBA dye is preferably in a range of 500 nm±30 nm, 490 nm±35 nm, or 580 nm±35 nm, respectively.

A carrier transport layer 4 to be packed in the space between the porous semiconductor layer 6 and the transparent conductive layer 7 is made of a conductive material capable of transporting electrons, holes, or ions. Examples of such a material are hole transporting materials such as polyvinyl carboazole and triphenylamine; electron transporting materials such as tetranitrofluorenone; conductive polymers such as polypyrrole; ion conductors such as a liquid electrolytic substance and an electrolytic polymer; and inorganic p-type semiconductors such as copper iodine and copper thiocyanate.

Among the above-mentioned conductive materials, ion conductors are preferable and a liquid electrolyte containing a redox electrolyte is especially preferable. As such a redox electrolyte, those which are generally usable for a battery and a solar cell can be used without any particular limitation. Practically, combinations of iodine with metal iodides such as LiI, NaI, KI and CaI₂ and combinations of bormine with metal bromides such as LiBr, NaBr, KBr and CaBr₂ are preferable, and particularly, the combination of LiI and iodine is especially preferable.

As a solvent for the liquid electrolyte, carbonate compounds such as propylene carbonate; nitrile compounds such as acetonitrile; alcohols such as ethanol; and further water and non-protonic polar substances can be used, and particularly, carbonate compounds and nitrile compounds are especially preferable. These solvents may be used in the form of a mixture of two or more of them. The concentration of the liquid electrolyte is preferable 0.1 to 1.5 mol/l and more preferably 0.1 to 0.7 mol/l.

In the case where the material forming the carrier transport layer is liquid and possibly leaks out of a solar cell, the solar cell may be sealed with a sealing material (not shown in FIG. 1). As the sealing material, epoxy resins, silicon resins and thermoplastic resins can be used.

### EXAMPLES

The invention will be described more practically with reference to the following examples and comparative examples; however, the invention is not limited to the examples.

The examples and comparative examples will be described on the basis of FIG. 1 showing a schematic cross-sectional view of a layer structure of a dye-sensitized solar cell of the invention.

In FIG. 1, 1 and 8 denote supporting substrates; 2 and 7 denote transparent conductive layers; 3 denotes a platinum layer; 4 denotes a carrier transport layer; 5 denotes a dye sensitizer; 6 denotes a porous semiconductor layer; e⁻ and arrow marks show the electric current. The transparent conductive layer 2 and the platinum layer 3 in combination are all together referred to as an counter electrode in some cases.

### Example 1

Formation of Porous Semiconductor Layer

To the supporting substrate 8 of a glass plate with transparent conductive layer 7 (manufactured by Nippon Sheet Glass Co., Ltd., Japan) was used. A commercially available titanium oxide paste (trade name: Ti-Nanoxide D/SP, average particle diameter: 13 nm, made by Solaronix Co., Swiss) was applied on the transparent conductive layer 7 side by doctor blade method and pre-heated at 300° C. for 30 minutes, and then calcined at 500° C. for 40 minutes to form a 6 μm-thick titanium oxide film as the porous semiconductor layer 6.

Formation of Photoelectrode

A dye solution with a concentration of 4×10⁻⁴ mol/l was prepared by dissolving cis-bis(isothiocyanato) bis(2,2′-bipyridyl-4,4′-dicarboxylato)ruthenium(II) as the dye sensitizer 5 (trade name: Ruthenium 535, made by Solaronix Co., Swiss) in ethanol (made by Aldrich Inc.). Next, the glass plate coated with the titanium oxide film was immersed in the obtained dye solution and kept for 30 minutes to adsorb the dye sensitizer in the titanium oxide film. The adsorbed dye concentration was 7×10⁻⁸ mol/cm² in the titanium oxide film.

After that, the glass plate coated with the titanium oxide film and adsorbing the dye sensitizer was washed with ethanol (made by Aldrich Inc.) and heated at a heating temperature of 130° C. for 30 minutes in atmospheric air in a drying furnace to obtain a photoelectrode.

The obtained photoelectrode was subjected to the absorbance measurement by an absorbance measurement apparatus (UV-3150 model, manufactured by Shimadzu Corporation, Japan) to find the absorbance peak at the longest wavelength side of the absorbance spectrum.

Production of Redox Electrolytic Solution

A redox electrolytic solution to be employed for the carrier transport layer 4 was prepared by dissolving lithium iodide (made by Aldrich Inc.) and iodine (made by Aldrich Inc.) in proper amounts to adjust the concentration to be 0.5 mol/l and 0.05 mol/l, respectively, in propylene carbonate (made by Aldrich Inc.) as a solvent.

Manufacturing of Dye-Sensitized Solar Cell

A 1 μm-thick platinum film as an counter electrode was formed by deposition on the transparent conductive layer 2 side of the supporting substrate 1, which was a transparent conductive glass plate same as the glass plate used for the production of the porous semiconductor layer, that is glass plate (manufactured by Nippon Sheet Glass Co., Ltd., Japan) coated with a SnO₂ film as the transparent conductive layer 2 by deposition. While a spacer for preventing short-circuit was inserted between the obtained counter electrode and the photoelectrode obtained as described above, the supporting substrate 1 and the supporting substrate 8 were layered. Next, the prepared redox electrolytic solution was injected into the gap between them and the side faces of them are sealed with an epoxy resin and lead wires are attached to the respective electrodes to obtain a dye-sensitized solar cell.

Light (AM 1.5 solar simulator) was radiated with an intensity of 1 kW/m² to the obtained dye-sensitized solar cell to evaluate the cell characteristics.

The obtained results as well as the absorbance peak are shown in Table 2.

### Comparative Example 1

A dye-sensitized solar cell was manufactured in the same manner as Example 1, except that the thermal treatment was not carried out in the photoelectrode production and evaluated.

The obtained results as well as the absorbance peak are shown in Table 2.

In the Table, Jsc, Vco, FF and Effi represent short-circuit current, open-circuit voltage, fill factor and conversion efficiency, respectively.

TABLE 2

| | Example 1 | Comparative Example 1 |
|---|---|---|
| Thermal treatment | Performed | Not performed |
| Absorbance peak (nm) | 509 | 540 |
| Jsc (mA/cm²) | 13.00 | 13.02 |
| Voc (V) | 0.78 | 0.70 |
| FF | 0.71 | 0.68 |
| Effi (%) | 7.20 | 6.20 |

From the results shown in Table 2, it was found that the dye-sensitized solar cell (Example 1) subjected to the thermal treatment in the photoelectrode production had the absorbance peak shifted to the shorter wavelength side of the absorbance spectrum than the dye-sensitized solar cell (Comparative Example 1) not subjected to the thermal treatment and was provided with improved photoelectric conversion efficiency.

### Example 2

A dye-sensitized solar cell was manufactured in the same manner as Example 1, except that cis-bis(isothiocyanato)bis(2,2′-bipyridyl-4,4′-dicarboxylato)-ruthenium(II)bis-tetrabutylammonium (trade name: Ruthenium 535-bisTBA dye, made by Solaronix Co., Swiss) was used in place of Ruthenium 535 dye as the dye sensitizer and evaluated.

The obtained results as well as the absorbance peak are shown in Table 3.

### Comparative Example 2

A dye-sensitized solar cell was manufactured in the same manner as Example 2, except that the thermal treatment was not carried out in the photoelectrode production and evaluated.

The obtained results as well as the absorbance peak are shown in Table 3.

TABLE 3

| | Example 2 | Comparative Example 2 |
|---|---|---|
| Thermal treatment | Performed | Not performed |
| Absorbance peak (nm) | 519 | 530 |
| Jsc (mA/cm²) | 14.02 | 14.19 |
| Voc (V) | 0.79 | 0.72 |
| FF | 0.71 | 0.69 |
| Effi (%) | 7.86 | 7.05 |

From the results shown in Table 3, it was found that the dye-sensitized solar cell (Example 2) subjected to the thermal treatment in the photoelectrode production had the absorbance peak shifted to the shorter wavelength side of the absorbance spectrum than the dye-sensitized solar cell (Comparative Example 2) not subjected to the thermal treatment and was provided with improved photoelectric conversion efficiency.

### Example 3

A dye-sensitized solar cell was manufactured in the same manner as Example 1, except that tris(isothiocyanato)-ruthenium(II)-2,2′:6′,2″-terpyridine-4,4′,4″-tricarboxylic acid, tris-tetrabutylammonium salt (trade name: Ruthenium 620-1H3TBA dye, made by Solaronix Co., Swiss) was used in place of Ruthenium 535 dye as the dye sensitizer and that chemical treatment was carried out in place of the thermal treatment in the photoelectrode production and then evaluated.

The chemical treatment was carried out by immersing the porous semiconductor layer-bearing substrate in a 50 mL acetonitrile (made by Kishida Chemical Co., Ltd., Japan) solution of 0.5 M dimethylpropylimidazolium iodide (made by Shikoku Corp., Japan) at 25° C. for 1 hour.

The obtained results as well as the absorbance peak are shown in Table 4.

### Comparative Example 3

A dye-sensitized solar cell was manufactured in the same manner as Example 3, except that the chemical treatment was not carried out in the photoelectrode production and evaluated.

The obtained results as well as the absorbance peak are shown in Table 4.

TABLE 4

| | Example 3 | Comparative Example 3 |
|---|---|---|
| Chemical treatment | Performed | Not performed |
| Absorbance peak (nm) | 602 | 620 |
| Jsc (mA/cm²) | 17.09 | 17.92 |
| Voc (V) | 0.75 | 0.68 |
| FF | 0.70 | 0.65 |
| Effi (%) | 8.97 | 7.92 |

From the results shown in Table 4, it was found that the dye-sensitized solar cell (Example 3) subjected to the chemical treatment in the photoelectrode production had the absorbance peak shifted to the shorter wavelength side of the absorbance spectrum than the dye-sensitized solar cell (Comparative Example 3) not subjected to the chemical treatment and was provided with improved photoelectric conversion efficiency.

### Example 4

A dye-sensitized solar cell was manufactured in the same manner as Example 1, except that Dye I expressed by the following formula was used in place of Ruthenium 535 dye as a dye sensitizer and that chemical treatment was carried out in place of the thermal treatment in the photoelectrode production and then evaluated.

The chemical treatment was carried out by immersing the porous semiconductor layer-bearing substrate in a 50 mL acetonitrile (made by Kishida Chemical Co., Ltd.) solution of 0.5 M dimethylpropylimidazolium iodide (made by Shikoku Corp., Japan) at 25° C. for 1 hour.

The obtained results as well as the absorbance peak are shown in Table 5.

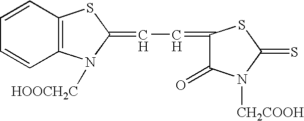

### Comparative Example 4

A dye-sensitized solar cell was manufactured in the same manner as Example 4, except that the chemical treatment was not carried out in the photoelectrode production and evaluated.

The obtained results as well as the absorbance peak are shown in Table 5.

TABLE 5

| | Example 4 | Comparative Example 4 |
|---|---|---|
| Chemical treatment | Performed | Not performed |
| Absorbance peak (nm) | 440 | 460 |
| Jsc (mA/cm²) | 11.22 | 11.92 |
| Voc (V) | 0.68 | 0.59 |
| FF | 0.67 | 0.58 |
| Effi (%) | 5.11 | 4.08 |

From the results shown in Table 5, it was found that the dye-sensitized solar cell (Example 4) subjected to the chemical treatment in the photoelectrode production had the absorbance peak shifted to the shorter wavelength side of the absorbance spectrum than the dye-sensitized solar cell (Comparative Example 4) not subjected to the chemical treatment and was provided with improved photoelectric conversion efficiency.

### Example 5

A dye-sensitized solar cell was manufactured in the same manner as Example 1, except that Ruthenium 620 dye (trade name: Ruthenium 620, made by Solaronix Co., Swiss) was used as the dye sensitizer and that chemical treatment was carried out in place of the thermal treatment in the photoelectrode production and then evaluated.

The chemical treatment was carried out by immersing the porous semiconductor layer-bearing substrate in a 50 mL acetonitrile (made by Kishida Chemical Co., Ltd., Japan) solution of 0.5 M ethylmethylpropylimidazolium iodide (made by Tomiyama Pure Chemical Industries. Ltd., Japan) at 25° C. for 1 hour.

TABLE 6

| | Example 5 |
|---|---|
| Chemical treatment | Performed |
| Absorbance peak (nm) | 595 |
| Jsc (mA/cm²) | 16.9 |
| Voc (V) | 0.78 |
| FF | 0.69 |
| Effi (%) | 9.10 |

### Example 6

A dye-sensitized solar cell was manufactured in the same manner as Example 1, except that cis-bis(isothiocyanato)bis(2,2′-bipyridyl-4,4′-dicarboxylato)-ruthenium(II)bis-tetrabutylammonium (trade name: Ruthenium 535-bisTBA dye, made by Solaronix Co., Swiss) was used in place of Ruthenium 535 dye as a dye sensitizer and that chemical treatment was carried out in place of the thermal treatment in the photoelectrode production and then evaluated.

The chemical treatment was carried out by immersing the porous semiconductor layer-bearing substrate in a 50 mL acetonitrile (made by Kishida Chemical Co., Ltd., Japan) solution of 0.5 M methylpropylimidazolium iodide (made by Tomiyama Pure Chemical Industries. Ltd., Japan) at 25° C. for 1 hour.

TABLE 7

| | Example 6 |
|---|---|
| Chemical treatment | Performed |
| Absorbance peak (nm) | 515 |
| Jsc (mA/cm²) | 14.04 |
| Voc (V) | 0.80 |
| FF | 0.71 |
| Effi (%) | 8.00 |

What is claimed is:

1. A dye-sensitized solar cell comprising a transparent conductive layer, a porous semiconductor layer on which a dye sensitizer is adsorbed, a carrier transport layer and an counter electrode which are formed in this order on a transparent substrate,
wherein an absorbance peak of the porous semiconductor layer is located on a shorter wavelength side of the absorbance spectrum than that of the porous semiconductor layer observed immediately after the dye sensitizer is adsorbed.

2. The dye-sensitized solar cell of claim 1, wherein the porous semiconductor layer is made of titanium oxide.

3. The dye-sensitized solar cell of claim 1, wherein the dye sensitizer is made of an organic dye or a metal complex dye.

4. The dye-sensitized solar cell of claim 1, wherein the dye sensitizer is made of cis-bis(isothiocyanato)bis(2,2′-bipyridyl-4,4′-dicarboxylato)-ruthenium(II) and the absorbance peak of the porous semiconductor layer is located within the range of 500 nm±30 nm.

5. The dye-sensitized solar cell of claim 1, wherein the dye sensitizer is made of cis-bis(isothiocyanato)bis(2,2′-bipyridyl-4,4′-dicarboxylato)-ruthenium(II)bis-tetrabutylammonium and the absorbance peak of the porous semiconductor layer is located within the range of 490 nm±35 nm.

6. The dye-sensitized solar cell of claim 1, wherein the dye sensitizer is made of tris(isothiocyanato)-ruthenium(II)-2,2′:6′,2″-terpyridine-4,4′,4″-tricarboxylic acid, tris-tetrabutylammonium salt having the formula (1): 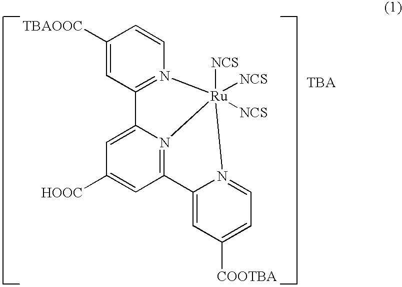
(wherein TBA is tetrabutylammonium residual group) and the absorbance peak of the porous semiconductor layer is located within the range of 580 nm±35 nm.

7 The dye-sensitized solar cell of claim 2, wherein the dye sensitizer is made of cis-bis(isothiocyanato)bis(2,2′-bipyridyl-4,4′-dicarboxylato)-ruthenium(II) and the absorbance peak of the porous semiconductor layer is located within the range of 500 nm±30 nm.

8. The dye-sensitized solar cell of claim 2, wherein the dye sensitizer is made of cis-bis(isothiocyanato)bis(2,2′-bipyridyl-4,4′-dicarboxylato)-ruthenium(II)bis-tetrabutylammonium and the absorbance peak of the porous semiconductor layer is located within the range of 490 nm±35 nm.

9. The dye-sensitized solar cell of claim 2, wherein the dye sensitizer is made of tris(isothiocyanato)-ruthenium(II)-2,2′:6′,2″-terpyridine-4,4′,4″-tricarboxylic acid, tris-tetrabutylammonium salt having the formula (1): 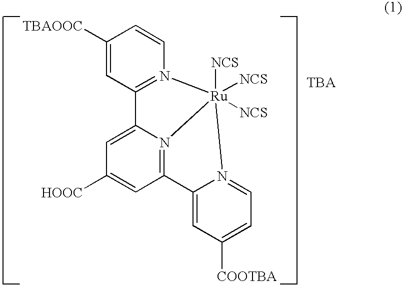
(wherein TBA is tetrabutylammonium residual group) and the absorbance peak of the porous semiconductor layer is located within the range of 580 nm±35 nm.

10. A manufacturing method of a dye-sensitized solar cell comprising a transparent conductive layer, a porous semiconductor layer on which a dye sensitizer is adsorbed, a carrier transport layer and an counter electrode which are formed in this order on a transparent substrate, comprising:
the step of shifting an absorbance peak of the porous semiconductor layer to a shorter wavelength side of the absorbance spectrum than that of the porous semiconductor layer observed immediately after the dye sensitizer is adsorbed.

11. The manufacturing method of claim 10, wherein the step of shifting the absorbance peak of the porous semiconductor layer is carried out after the dye sensitizer is adsorbed in the porous semiconductor layer.

12. The manufacturing method of claim 10, wherein the step of shifting the absorbance peak of the porous semiconductor layer is carried out by a thermal treatment.

13. The manufacturing method of claim 12, wherein the thermal treatment is carried out at 100 to 180° C.

14. The manufacturing method of claim 10, wherein the step of shifting the absorbance peak of the porous semiconductor layer is carried out by a chemical treatment.

15. The manufacturing method of claim 14, wherein the chemical treatment is carried out by using a solution containing at least one heteroatom-containing cyclic compound.

16. The manufacturing method of claim 15, wherein the chemical treatment is carried out by immersing in the solution for 1 minute to 30 hours the porous semiconductor layer after the dye sensitizer is adsorbed.

17. The manufacturing method of claim 15, wherein the heteroatom-containing cyclic compound is a nitrogen-containing cyclic compound.

18. The manufacturing method of claim 17, wherein the heteroatom-containing cyclic compound has two or more nitrogen atoms.

19. The manufacturing method of claim 15, wherein the heteroatom-containing cyclic compound is a nitrogen-containing cyclic compound including a substituted or unsubstituted 5-membered ring.

20. The manufacturing method of claim 10, wherein the absorbance peak of the porous semiconductor layer is shifted to the shorter wavelength side of the absorbance spectrum by 10 to 60 nm than that of the porous semiconductor layer observed immediately after the dye sensitizer is adsorbed.
